(19) United States
(12) Patent Application Publication
(10) Pub. No.: US 2011/0100412 A1
(43) Pub. Date: May 5, 2011

(54) METHOD OF MANUFACTURING PHOTOVOLTAIC MODULES

(75) Inventors: Lawrence A. Clevenger, Hopewell Junction, NY (US); Rainer Krause, Mainz (DE); Karl-Heinz Lehnert, Mainz (DE); Gerd Pfeiffer, Hopewell Junction, NY (US); Kevin Prettyman, Hopewell Junction, NY (US)

(73) Assignee: International Business Machines Corporation, Armonk, NY (US)

(21) Appl. No.: 12/825,649

(22) Filed: Jun. 29, 2010

(30) Foreign Application Priority Data
Oct. 30, 2009 (DE) EP09174556

(51) Int. Cl. H01L 31/042; H01L 31/18

(52) U.S. Cl. 136/244; 438/4; 257/E21.499

(57) ABSTRACT

A photovoltaic module and a method of manufacturing such a module in which metal is deposited in a pattern on the front side of a semiconductor wafer which acts as an electrode. Photovoltaic cells manufactured using a semiconductor wafer typically have a P type semiconductor region and an N type semiconductor region. The metal on the front side of each of the photovoltaic cells forms an electrical connection to the doped layer of the semiconductor wafer on its front side.

### FIELD OF AND BACKGROUND THE INVENTION

The invention relates to photovoltaic modules, and in particular to methods of manufacturing photovoltaic modules.

One way of manufacturing photovoltaic modules is to connect together a plurality of photovoltaic cells. The photovoltaic cells may be connected in series, parallel, or a combination of series and parallel. Typically photovoltaic cells are connected in series, because the electrical power produced by the photovoltaic cells is a smaller voltage (approximately 0.6V) and with a larger current (approximately 6.5 A), while the module should have larger voltage and smaller current. This reduces power losses in the wiring coming from the photovoltaic panel.

As used herein the term photovoltaic cell refers to a photovoltaic cell that is either completed in all of its manufacturing steps and is fully functional or has been partially manufactured. For instance the term photovoltaic cell may refer to a finished photovoltaic cell, a semiconductor wafer, or at an intermediate point of manufacture between being a semiconductor wafer and a photovoltaic cell. The term photovoltaic module refers to a plurality of photovoltaic cells coupled together.

U.S. Pat. No. 5,504,015 discloses a method of manufacturing photovoltaic modules. Conducting tracks are deposited on a glass sheet in positions exactly corresponding to the rear contacts already deposited on the rear of silicon wafers. The glass sheet is superposed on the silicon wafers such that the two series of contacts are juxtaposed. At this point a vacuum is released and the “sandwich” of the wafers and the glass sheet is heated to about 200 degrees Celsius.

A difficulty in manufacturing photovoltaic modules or panels is that varying electrical properties of photovoltaic cells may limit the overall efficiency of the photovoltaic panel. For instance, if a plurality of photovoltaic cells are connected in series a photovoltaic cell which produces a lower current will limit the current of the other cells and reduce the efficiency of the entire photovoltaic module. Embodiments of the disclosure made here provide for reworking a photovoltaic panel by using flex connectors to form an electrical connection between a plurality of photovoltaic cells.

### SUMMARY OF THE INVENTION

The invention described here provides for a method of manufacturing a photovoltaic module, and a photovoltaic module apparatus.

The invention provides for a method of manufacturing a photovoltaic module. The photovoltaic module comprises a plurality of photovoltaic cells. Each of the photovoltaic cells comprises a semiconductor wafer. There are two main methods of manufacturing photovoltaic cells. One way is using a solid semiconductor wafer and the other is using thin film technology. The method relates to manufacturing photovoltaic modules using a plurality of photovoltaic cells that comprise or are manufactured using a solid semiconductor wafer. Silicon wafers, either mono or poly crystalline are typically used for manufacturing this type of photovoltaic cell.

The method of manufacturing the photovoltaic module comprises the steps of depositing metal in a pattern on the front side of each of the photovoltaic cells. Photovoltaic cells manufactured using a semiconductor wafer have a metal pattern on the front side which acts as an electrode. Photovoltaic cells manufactured using a semiconductor wafer typically have a P type semiconductor region and an N type semiconductor region. The metal on the front side of each of the photovoltaic cells forms an electrical connection to the doped layer of the semiconductor wafer on its front side. After the metal is deposited each of the photovoltaic cells is annealed. Each of the photovoltaic cells can be annealed separately, or they can be annealed together.

The method further comprises placing each of the photovoltaic cells on a carrier. The annealing may take place before each of the photovoltaic cells is placed on the carrier, or it may occur after each of the photovoltaic cells is placed on the carrier. If the annealing takes place after each of the photovoltaic cells is placed on the carrier, then the carrier is constructed from a material which is able to withstand the thermal stress of being annealed along with the photovoltaic cells. The depositing of the metal and the pattern on the front side of each of the photovoltaic cells can occur before the photovoltaic cells are placed on a carrier, or it may also occur after the photovoltaic cells are placed on a carrier.

### BRIEF DESCRIPTION OF THE DRAWINGS

Some of the purposes of the invention having been stated, others will appear as the description proceeds, when taken in connection with the accompanying drawings, in which:

FIG. 1 illustrates a method of manufacturing a photovoltaic module according to an embodiment of the invention;

FIG. 2 illustrates a further method of manufacturing a photovoltaic module according to an embodiment of the invention;

FIG. 3 illustrates a photovoltaic module according to an embodiment of the invention;

FIG. 4 illustrates a further method of manufacturing a photovoltaic module according to an embodiment of the invention;

FIG. 5 illustrates a further method of manufacturing a photovoltaic module according to an embodiment of the invention;

FIG. 6 illustrates a further method of manufacturing a photovoltaic module according to an embodiment of the invention;

FIG. 7 illustrates a photovoltaic cell according to an embodiment of the invention;

FIG. 8 illustrates a partial module according to an embodiment of the invention assembled using photovoltaic cells as illustrated in FIG. 7; and

FIG. 9 illustrates a flex connector according to an embodiment of the invention.

### DETAILED DESCRIPTION OF THE INVENTION

While the present invention will be described more fully hereinafter with reference to the accompanying drawings, in which preferred embodiments of the present invention are shown, it is to be understood at the outset of the description which follows that persons of skill in the appropriate arts may modify the invention here described while still achieving the favorable results of the invention. Accordingly, the description which follows is to be understood as being a broad, teaching disclosure directed to persons of skill in the appropriate arts, and not as limiting upon the present invention. In the following, like numbered elements in the figures are either similar elements or perform an equivalent function. Elements which have been discussed previously will not necessarily be discussed in later figures if the function is equivalent.

Each of the photovoltaic cells has a front side and a backside. When the front side of a photovoltaic cell is exposed to illumination, the photovoltaic cell produces electricity. The photovoltaic module comprises a carrier adapted for receiving a plurality of photovoltaic cells. The carrier could be constructed in a variety of ways. The carrier could be a glass or ceramic substrate adapted for receiving the photovoltaic cells. The carrier could also be a metal or partially metal frame, tray, or carrier adapted for receiving the photovoltaic cells. The photovoltaic module further comprises a plurality of flex connectors. The flex connectors are adapted for making an electrical connection between the plurality of photovoltaic cells.

A flex connector as used herein is defined as a flexible connector adapted for connecting two photovoltaic cells together.

Typically photovoltaic cells are wired in series to increase the voltage delivered. By using a higher voltage, smaller wires are required for transmitting the electrical power to an inverter or other device which is going to use the electricity generated by the photovoltaic module. However, wiring the photovoltaic cells in series is not necessary, the photovoltaic cells can be wired in parallel or they may also be wired in combination of parallel and series arrangements.

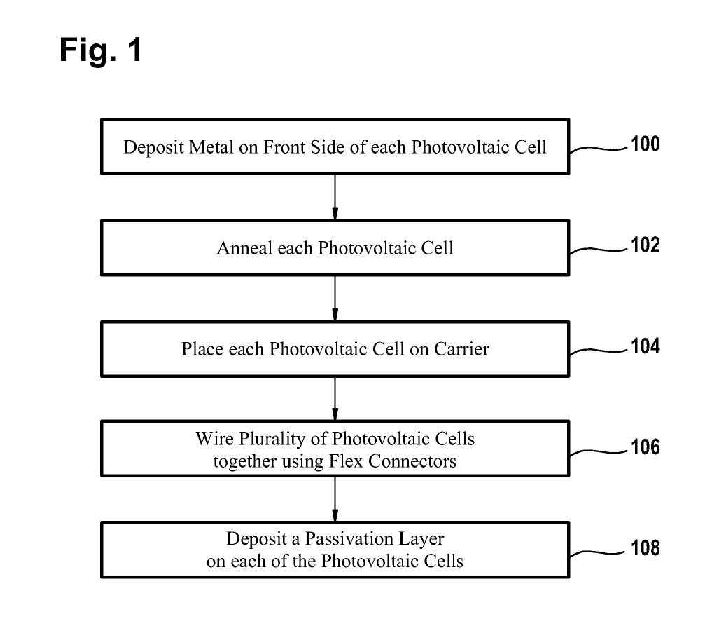

FIG. 1 illustrates a method according to an embodiment of the invention. In step 100 metal is deposited on the front side of each of a plurality of photovoltaic cells. In step 102 each photovoltaic cell is annealed. In step 104 each photovoltaic cell is placed on a carrier. The carrier is adapted for receiving the photovoltaic cells and forms a structural support for them. Alternatively, steps 100 and 102 may be performed after each photovoltaic cell is placed onto the carrier. In step 106 the plurality of photovoltaic cells is wired together using flex connectors. Finally in step 108 a passivation layer is deposited on each of the photovoltaic cells.

The metal can be deposited in a variety of ways on the photovoltaic cell. The metal may be deposited using screen printing or other printing process on the surface of each of the photovoltaic cells. When the metal is deposited after the photovoltaic cells are placed on the carrier, it may be done in a variety of ways. The metal may be deposited by printing on each individual photovoltaic cell or there may be a process where all of the cells are printed at once. Alternatively masks may be placed on the photovoltaic cells and a thin film deposition technique such as radio frequency sputtering using a plasma may be used to deposit metal on the front side of each of the photovoltaic cells.

The method further comprises wiring the plurality of photovoltaic cells together using flex connectors to form an electrical connection between the plurality of photovoltaic cells. After the photovoltaic cells have been wired together, a passivation layer is deposited on each of the photovoltaic cells. A passivation layer is defined herein as a layer deposited on the front side of a photovoltaic cell that passivates a semiconducting layer. The passivation layer is also understood herein to refer to an antireflective layer. The passivation layer is typically a silicon oxide or silicon nitride thin film.

In another embodiment the method further comprises the step of testing the electrical properties of the photovoltaic module before depositing the passivation or antireflective layer by illuminating the photovoltaic module. A critical point when manufacturing photovoltaic modules is that the electrical properties of the photovoltaic cells may not be identical. For instance if the current of the photovoltaic cells is different and they are wired in series then the efficiency of the photovoltaic module will be reduced by the photovoltaic cells or cell which has a lower current.

The method further comprises determining if each of the photovoltaic cells has at least one electrical property within a predetermined range. The electrical property is a function of illumination of the photovoltaic module. For instance, when the photovoltaic module is illuminated each cell will produce a particular current and voltage. The way in which the photovoltaic cells are wired or connected together determines which electrical properties are important. If the photovoltaic cell or a group of photovoltaic cells is wired together in parallel then the voltage is critical. If a photovoltaic cell or a group of photovoltaic cells is wired together in series then the current will be a critical electrical property to match. When wired in parallel it is beneficial if elements have a voltage within a predetermined voltage range and when wired in series it is beneficial if they have a current within a predetermined current range.

The method further comprises the step of removing any of the plurality of photovoltaic cells from the photovoltaic module that do not have one of the electrical properties within the predetermined range. If for instance a photovoltaic cell is in a series circuit with other photovoltaic cells and it produces a smaller current than the others, then this photovoltaic cell will reduce the efficiency of the entire photovoltaic module. By removing the photovoltaic cell and replacing it with one that better matches the electrical properties of the other photovoltaic cells in the photovoltaic module, the efficiency of the photovoltaic module can be improved.

The use of flex connectors facilitates the removal of any of the plurality of photovoltaic cells. If the flex connectors are soldered to the photovoltaic cells, then a particular photovoltaic cell may be unsoldered and removed from the photovoltaic module. The method further comprises replacing the removed photovoltaic cell with a replacement photovoltaic cell. The replacement photovoltaic cell will have an electrical property that is within the predetermined range. As was explained above, this will lead to an improved efficiency for the entire photovoltaic module

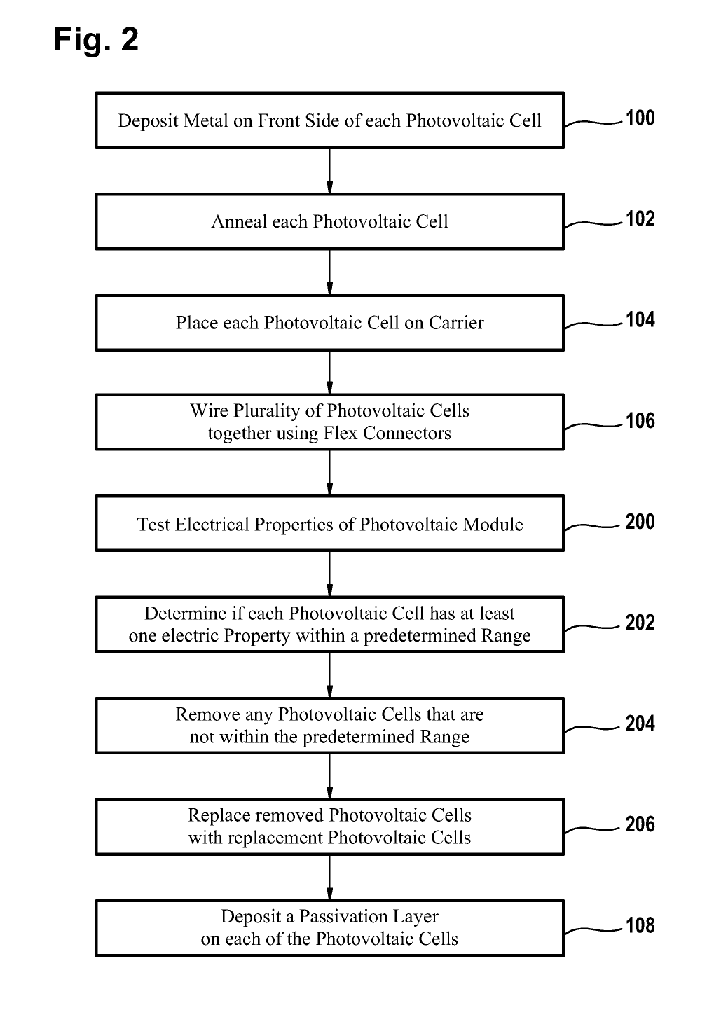

FIG. 2 shows an additional embodiment of a method according to an embodiment of the invention. The method shown in FIG. 2 is identical to that of FIG. 1 except after step 106 additional steps have been added before step 108 is performed. After step 106 is performed, step 200 is performed. In step 200 the electrical properties of the photovoltaic module are tested. The photovoltaic module is illuminated and it is determined whether it produces the proper voltage and current. During this testing process step 202 is also performed. It is determined if each photovoltaic cell has at least one electrical property within a predetermined range. In step 204 any photovoltaic cells which are not within the predetermined range are removed from the photovoltaic module.

The use of flex connectors allows photovoltaic cells which have been wired into the photovoltaic cell to be removed. In step 206 photovoltaic cells which were removed are replaced with replacement photovoltaic cells. The replacement photovoltaic cells have electrical characteristics which are within the predetermined range. Adding these replacement photovoltaic cells in place of the removed photovoltaic cells improves the efficiency of the photovoltaic module. Then finally in step 108 a passivation layer is deposited on each of the photovoltaic cells.

In another embodiment, the deposition of metal in a pattern on the front side of each of the photovoltaic cells is performed before each of the photovoltaic cells is placed on the carrier. In this embodiment the photovoltaic cells may be manufactured before they are placed on the carrier.

In another embodiment the annealing is performed before placing each of the photovoltaic cells on the carrier. The method further comprises the step of measuring at least one electrical property of each of the photovoltaic cells. The electrical property of each of the photovoltaic cells is a function of illumination on the front side. In this embodiment the annealing is performed before the photovoltaic cells are placed on the carrier. In this way the electrical property or properties of the photovoltaic cell can be measured before it is assembled into a photovoltaic module. This would facilitate constructing a photovoltaic module out of photovoltaic cells which have electrical properties that better match. This allows a photovoltaic module with a higher efficiency to be constructed. However, even with performing the step it still may be beneficial to test the final photovoltaic module before depositing the passivation layer. This is because even with pre-sorting photovoltaic cells according to their electrical properties, a photovoltaic module with a lower than expected efficiency may still be produced.

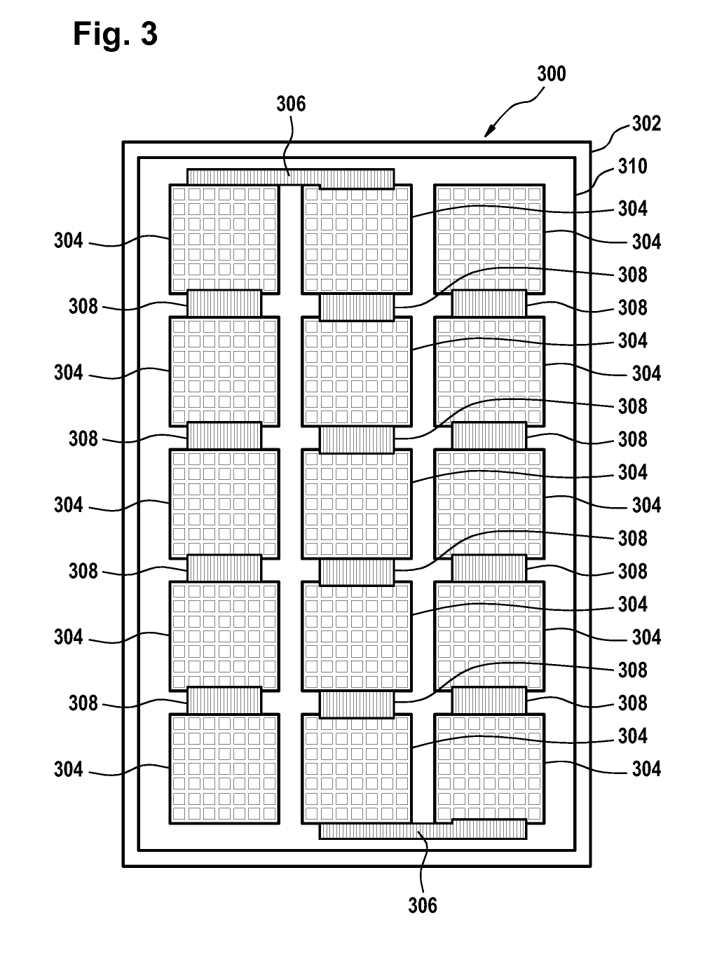

FIG. 3 illustrates a photovoltaic module according to an embodiment of the invention. The photovoltaic module 300 comprises a carrier 302. Upon the carrier 302 is an array of photovoltaic cells 304. The photovoltaic cells 304 are connected together electrically using flex connectors 306, 308. The flex connectors 306, 308 connect to bus bars on the underside of the photovoltaic cells 304 and connect to the bus bars on the front side of the adjacent photovoltaic cell 304. Because the connectors 306, 308 are flexible, an operator will be able to de-solder or re-solder individual photovoltaic cells 304. This facilitates the removal and replacement of an individual photovoltaic cell 304 which fails a test of its electrical properties.

Two types of flex connectors 306, 308 are shown. There are flex connectors 308 which connect adjacent photovoltaic cells in the same row. There are also flex connectors 306 between different rows of photovoltaic cells 304. This is an illustration of how the exact geometry and shape of a flex connector 306, 308 can be adapted to the various geometry and methods of wiring the photovoltaic cells 304 in a photovoltaic module 300.

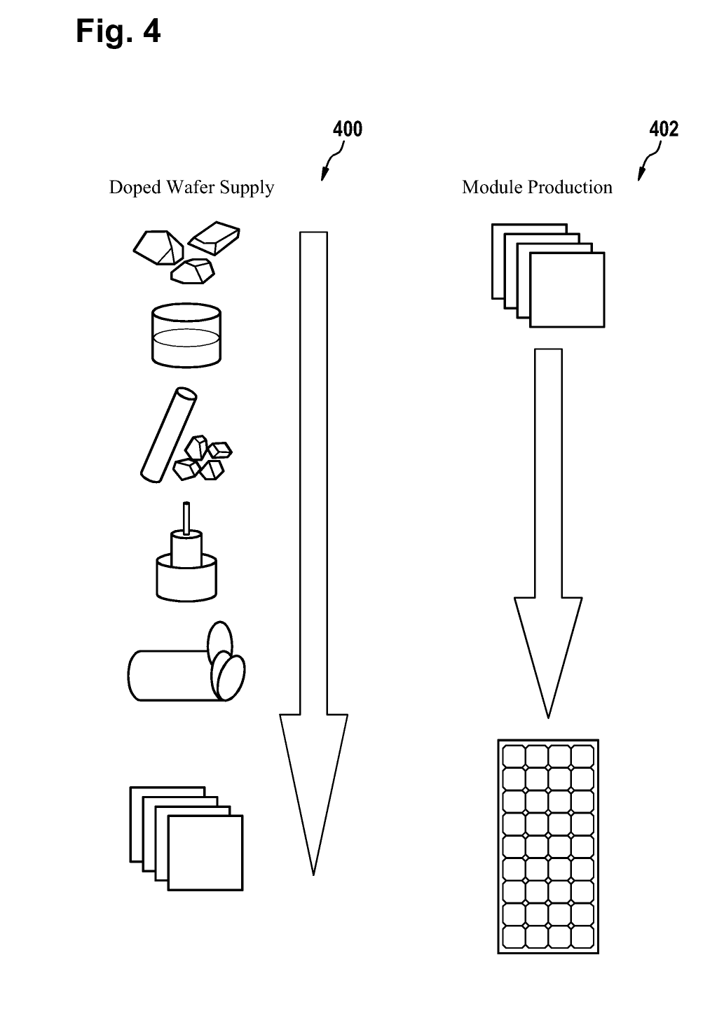

FIG. 4 shows an embodiment of a method according to the invention. The method of manufacturing a photovoltaic module is broken into two main manufacturing steps. The first main manufacturing is the doped wafer supply 400. The second procedure turns the doped wafers into a photovoltaic module. The second procedure is module production 402.

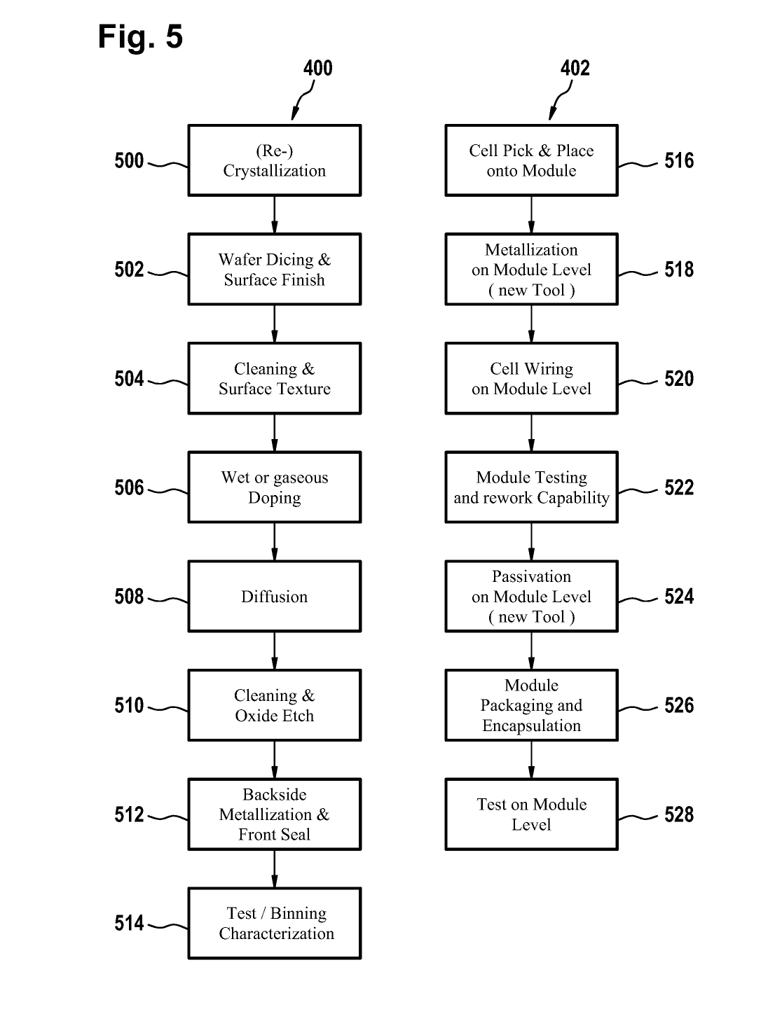

FIG. 5 shows a more detailed description of the process flow for manufacturing a photovoltaic module according to an embodiment of the invention. Again there are two main branches, the first is the doped wafer supply 400 and the module production 402. In step 500 crystallization or re-crystallization of a semiconductor material such as silicon is performed. In step 502 wafer dicing and surface finishing is performed. In step 504 cleaning and surface texturing is performed. A surface texturing may reduce the reflectivity of the surface of the semiconductor wafer and therefore may increase the efficiency of a photovoltaic cell. In step 506 the wafer is doped either using a gaseous or a wet process. In a wet process a semiconductor wafer is exposed to a liquid bath, mist, or vapors which condense on the surface of the semiconductor wafer.

In step 508 the doped wafer is then put into a diffusion oven 508. The heat treating of the wafer allows the doping material to diffuse into the semiconductor wafer. During the diffusion process an oxide may build up on the surface of the semiconductor wafer. This is very typical for silicon wafers. In step 510 a cleaning an oxide etch step is performed. This is very typically a hydrofluoric acid based chemical wet etch. In step 512 backside metallization and front seal is performed. In step 514 the wafers may be tested and sorted according to their characteristics. For example, the rear electrode or metallization may be tested for the quality of its electrical connection.

In another embodiment the deposition of metal in a pattern on the front side of each of the photovoltaic cells is performed after the plurality of photovoltaic cells are placed on the carrier. This embodiment is advantageous, because a large group of photovoltaic cells are patterned and annealed all in the same step. This may lead to improved manufacturing efficiency.

In another embodiment the method further comprises the step of measuring the cleanliness of each of the plurality of photovoltaic cells. The method further comprises the step of cleaning each of the plurality of photovoltaic cells if the cleanliness of each of the plurality of photovoltaic cells is below a predetermined measure. When photovoltaic cells are manufactured, they are typically coated with a doping agent using a wet, gaseous, or vaporous process before being treated in a diffusion furnace. This method is beneficial, because dust or particulates can settle on the surface of the wafer and cause non-uniform doping of the front surface. Dust on the surface may be measured using a camera inspection system or by a laser inspection system that measures laser light scattered by the particulates. Cleaning may be performed by washing the surface, blowing particulates off of the surface, or by mechanically brushing particulates off of the surface. Followed e.g. by spin or heat drying.

In another embodiment, the method further comprises the step of performing a surface characterization of each of the plurality of photovoltaic cells before a step of surface texturing is performed. The front surface of a photovoltaic cell may be textured to reduce the reflectivity of the surface and therefore increase its efficiency. This embodiment is beneficial, because a measurement such as a sheet resistance measurement may be performed. This allows better sorting and characterization of the photovoltaic cells.

In another embodiment the method further comprises the steps of metalizing the backside of each of the photovoltaic cells. The method further comprises the step of characterizing electrical connection of the backside metallization before depositing metal in a pattern on the front side. The method further comprises characterizing the surface of the front side before depositing metal in a pattern on the front side. The addition of these steps is advantageous, because both the electrical connection of the backside metallization and the surface of the front side are characterized before the photovoltaic cell is used to manufacture a photovoltaic module. Characterizing the electrical connection on the backside allows the detection of a bad connection. Characterizing the surface of the front side by performing a surface analysis may allow the detection of defects on the front side before metallization occurs.

In another embodiment two bus bars are metalized on the backside of each of the photovoltaic cells. These two bus bars may be used for forming an electrical connection with the flex connectors.

In another embodiment the pattern of the deposited metal on the front side of each of the photovoltaic cells has at least three bus bars. The depositing of metal on the front side of each of the photovoltaic cells before a passivation or antireflective layer is deposited on the front side allows a higher quality electrode to be formed on the front side of each of the photovoltaic cells. Normally a passivation and/or antireflective layer is deposited on each of the photovoltaic cells before metal is deposited and patterned on the photovoltaic cells. The reason for this is that the photovoltaic cells need to be wired together. If a passivation or antireflective layer is deposited after the metal, then there is no way to form an electrical connection to the front electrode formed by the metal.

In the manufacturing process of the present invention, the passivation layer is deposited after the photovoltaic cells have been wired together. This allows a metal pattern to be deposited before the passivation layer. This has several advantages, first the annealing temperature is lower because the metal does not need to go through the passivation and/or antireflective layer. Additionally, the metal pattern may be designed differently. A pattern with thinner bus bars may be used. By using thinner bus bars and increasing the number of bus bars, the shading of the photovoltaic cells by the bus bars is reduced. This leads to an increased efficiency of the photovoltaic cell.

Similarly the surface of the wafer may be inspected for defects, for instance during wet or gaseous doping dust may be on the surface of the wafer. This may cause non-uniform doping on the surface of the silicon wafer. After this is performed, step 516 is then performed. The cell is picked and placed onto the carrier of the module 516. In step 518 metallization is performed on the front surface of the silicon wafer. This includes depositing a metal pattern on the front surface of the wafer and annealing it. In step 520 the photovoltaic cells are wired together on the module level. In step 522 the photovoltaic module is tested and it is possible to rework the photovoltaic module in this step.

In step 524 passivation is performed on a module level. This is a layer which may be used for passivation of the exposed semiconductor surface, or it may also be an antireflective coating. The passivation and/or antireflective coating are very typically silicon oxide layers or silicon nitride layers. The passivation of an entire photovoltaic module can be accomplished using a plasma based deposition tool. This can be accomplished using a chemical vapor deposition technique or it may also be accomplished using a radio frequency sputtering technique. In step 526 the photovoltaic module is packaged and encapsulated. A structure of glass or transparent plastic may be placed over the photovoltaic module to protect the photovoltaic cells and to hold them into place. In step 528 the photovoltaic module is tested on a module level.

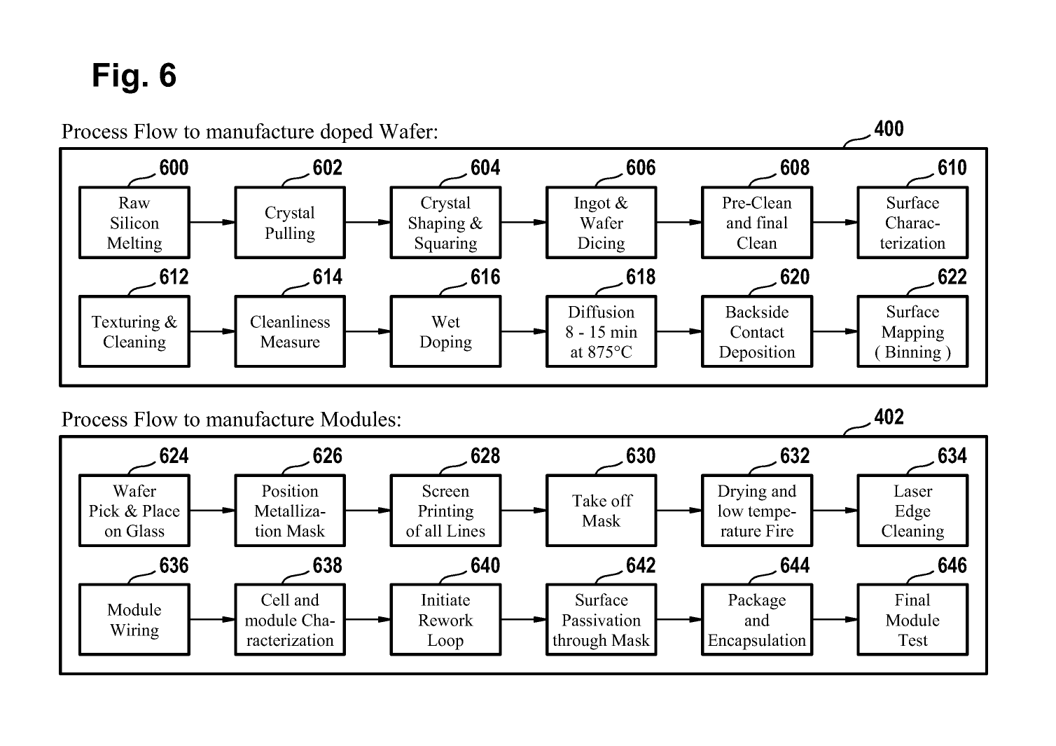

FIG. 6 shows another illustration of a method according to an embodiment of the invention. Then the process is divided into two major process flows. The first process flow 400 is the doped wafer manufacturing and the second is the process flow 402 for manufacturing a photovoltaic module. In step 600 raw silicon is melted. In step 602 crystal pooling is performed to manufacture a single crystal ingot. In step 604 crystal shaping and squaring is performed. In step 606 the ingot and wafers produced from the ingot are diced. In step 608 a pre-clean and final clean is performed. In step 610 an initial surface characterization is performed. In step 612 texturing and cleaning of the wafers is performed. In step 614 a cleanliness measurement is performed to ensure that the wafer is clean before wet doping 616 is performed. After the wet doping 616 diffusion is performed in a furnace for 8-15 minutes at 875 degrees Celsius.

In step 620 backside contact deposition is performed. In step 622 surface mapping is performed and wafers are sorted according to their surface properties. Now that a doped wafer has been manufactured the process flow for manufacturing a module 402 is described. In step 624 wafers are picked up and placed on a glass substrate. In step 626 a mask for metallization is positioned. In step 628 screen printing of all lines on the front surface of the wafers is performed. In step 630 the mask is removed. In step 632 the metal, which was screen printed on the wafer, is allowed to dry and then annealed in a low temperature furnace.

In step 634 laser etch cleaning is performed to electrically isolate the front and the back surfaces. In step 636 wiring is performed on the module level. In step 638 both the photovoltaic module and the individual photovoltaic cells are characterized electrically. In step 640 the re-work loop is initiated. During this loop cells which did not test as meeting sufficient electrical characteristics are removed and replaced with other cells. In step 624 surface passivation is performed through a mask. The mask reduces the area of the carrier and the flex connectors that are coated when the passivation layer is being deposited. In some embodiments a mask is not used. In step 644 the photovoltaic module is packaged and encapsulated. In step 646 the module is subjected to final tested and quality inspections.

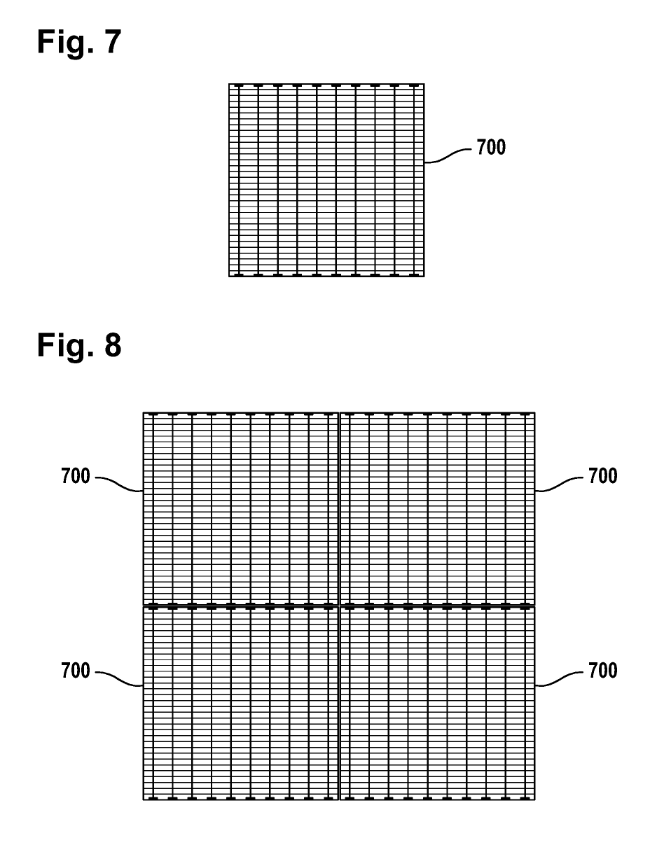

FIG. 7 shows an example of a photovoltaic cell 700 according to an embodiment of the invention. Visible is the metallization pattern on the surface of the photovoltaic cell 700.

In another aspect the invention provides for a photovoltaic module. The photovoltaic module comprises a plurality of photovoltaic cells. Each of the photovoltaic cells comprises a semiconductor wafer. Each of the photovoltaic cells has a front side and a backside. Each of the photovoltaic cells produces electricity when illuminated on the front side. The photovoltaic module further comprises a carrier adapted for receiving a plurality of photovoltaic cells. The plurality of flex connectors form electrical connections between the plurality of photovoltaic cells. A metal pattern is deposited on the front side of each of the photovoltaic cells. The plurality of photovoltaic cells are wired together to form an electrical connection. There is a passivation layer deposited over the metal pattern of each of the plurality of photovoltaic cells. The advantages of such a photovoltaic module has already been discussed in the context of the manufacturing method

An advantage of manufacturing a photovoltaic module using a method according to an embodiment of the invention may be that the width of the bus bar may be reduced. This is because the metallization is performed before the passivation and/or antireflective layer is deposited. The passivation and/or antireflective layer may off the benefit of protecting the metal grid. The late passivation enables a firing of the surface layer with much less furnace temperature. If a thin metal film is sputter deposited using a plasma, the annealing step may be used to decrease the contact resistance with the top surface.

The metallization for a single cell is shown in the FIG. 7. The horizontal lines are the regular contact grid. The ten vertical lines are the two bus bar replacements, each may be required to carry approximately 0.64 Amps. Fewer bus bars may be used, but they would need to be wider to carry the required current load. An advantage of this embodiment is that the shadowing by the bus bars is reduced, which leads to an increased efficiency for the photovoltaic cells and the photovoltaic module.

FIG. 8 shows a partial module view comprising four photovoltaic cells 700. this figure is illustrative of how a plurality of photovoltaic cells may be used to form a photovoltaic module.

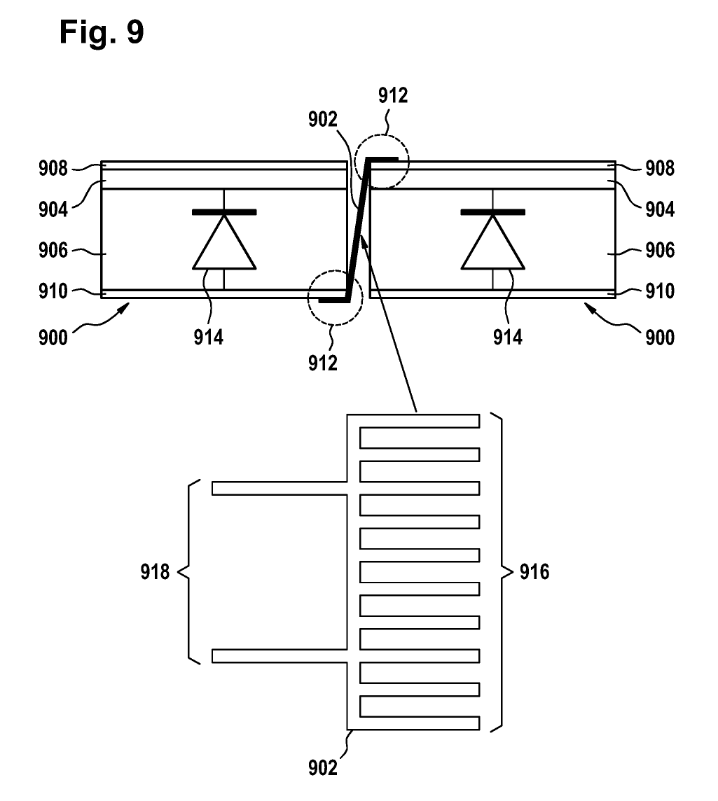

FIG. 9 illustrates the wiring of two photovoltaic cells 900 in serial. Shown is a flex connector 902 which connects the back metallization 910 of one photovoltaic cell 900 to the front metallization 908 of a different photovoltaic cell 900. Each photovoltaic cell 900 has a front metallization 908 and a back metallization 910. In contact with the front metallization 908 is an N type layer 904 of the photovoltaic cell 900. In contact with both the N type layer 904 and the back metallization 910 is the P type layer 906. The PN junction formed by the N type layer 904 and the P type layer 906 is represented in the diagram by a diode 914. The flex connector 902 is illustrated as having on one side connections for the ten bus bars 916 to connect to the top metallization 908 and having dual bus bars on the other end 918 for connecting to the bus bars of the back metallization 910.

In the drawings and specifications there has been set forth preferred embodiments of the invention and, although specific terms are used, the description thus given uses terminology in a generic and descriptive sense only and not for purposes of limitation.

What is claimed is:

1. A method comprising:
depositing metal in a pattern on the front side of a photovoltaic cell formed on a semiconductor wafer to have a front side and a back side, the cell producing electricity when the front side is illuminated;
annealing the photovoltaic cell after depositing metal;
placing a plurality of photovoltaic cells on a carrier;
wiring the plurality of photovoltaic cells together using flex connectors to form an electrical connection between and among the plurality of photovoltaic cells; and
depositing a passivation layer on each of the plurality of photovoltaic cells after wiring the plurality of photovoltaic cells together.

2. The method of claim 1, further comprising:
testing the electrical properties of the photovoltaic module before depositing the passivation layer by illuminating the photovoltaic module;
determining if each of the plurality of photovoltaic cells has at least one electrical property within a predetermined range, the electrical property being a function of the illumination of the photovoltaic module;
removing from the photovoltaic module any of the plurality of photovoltaic cells that do not have at least one of the electrical properties within the predetermined range; and
replacing the removed photovoltaic cells with replacement photovoltaic cells which have electrical properties that are within the predetermined range.

3. The method of claim 1, wherein the deposition of metal in a pattern on the front side of each of the plurality of photovoltaic cells is performed before each of the photovoltaic cells is placed on the carrier.

4. The method of claim 3, wherein the annealing is performed before placing each of the plurality of photovoltaic cells on the carrier, and further comprising the step of measuring at least one electrical property of each of the plurality of photovoltaic cells, wherein the electrical property of each of the photovoltaic cells is a function of illumination on the front side.

5. The method of claim 1, wherein the deposition of metal in a pattern on front side of each of the plurality of photovoltaic cells is performed after the plurality of photovoltaic cells is placed on the carrier.

6. The method of claim 1 further comprising:
measuring the cleanliness of each of the plurality of photovoltaic cells; and cleaning each of the plurality of photovoltaic cells if the cleanliness of each of the plurality of photovoltaic cells is below a predetermined measure.

7. The method of claim 1 further comprising performing a surface characterization of each of the plurality of photovoltaic cells and performing surface texturing.

8. The method of claim 1 further comprising:
metalizing the backside of each of the plurality of photovoltaic cells,
characterizing the electrical connection of the backside metallization before depositing metal in a pattern on the front side; and
characterizing the surface of the front side before depositing metal in a pattern on the front side;

9. The method according to claim 8, wherein two bus bars are metalized on the backside of each of the plurality of photovoltaic cells.

10. The method according to claim 9, wherein the metalization forms at least three bus bars.

11. The method according to claim 10, wherein the pattern has tenbus bars.

12. A product comprising:
a plurality of photovoltaic cells, each of said plurality of photovoltaic cells comprising a semiconductor wafer and having a front side and a back side, each of said photovoltaic cells producing electricity when the front side is illuminated;
a carrier which receives said plurality of photovoltaic cells;
a plurality of flex connectors forming electrical connections between and among the plurality of photovoltaic cells, said plurality of photovoltaic cells being wired together to form an electrical connection;
a metal pattern deposited on the front side of each of the photovoltaic cells; and
a passivation layer deposited over the metal pattern of each of the plurality of photovoltaic cells;

13. The product of claim 13, wherein the plurality of flex connectors and the carrier are at least partially coated with the passivation layer.
